(19) United States
(12) Patent Application Publication
(10) Pub. No.: US 2019/0334054 A1
(43) Pub. Date: Oct. 31, 2019

(54) Wafer processing system

(71) Applicant: Beijing Chuangyu Technology Co., Ltd, Beijing (CN)

(72) Inventors: Min WEI, Beijing (CN); Jincheng ZOU, Beijing (CN); Bingbing SHEN, Beijing (CN); Wei LI, Beijing (CN); Jingmiao WANG, Beijing (CN); Wei YANG, Beijing (CN)

(21) Appl. No.: 16/022,730

(22) Filed: Jun. 29, 2018

(30) Foreign Application Priority Data
Apr. 27, 2018 (CN) 201810394867.8

(51) Int. Cl. H01L 31/18; H01L 21/67; H01L 21/677

(52) U.S. Cl. CPC H01L 31/1876; H01L 21/67075; H01L 31/1892; H01L 21/67259; H01L 21/67742

(57) ABSTRACT

The present disclosure relates to the field of wafer processing, and discloses a wafer processing system. A wafer includes a substrate and a film on the substrate. The wafer processing system includes: an etching unit, configured to output a plurality of wafers to be separated; and a separation unit, including at least two first carrying platforms and a manipulator component, wherein the first carrying platforms are provided on a side of the etching unit, and are configured to carry the plurality of wafers to be separated, and the manipulator component is switched in turns at each position of all the first carrying platforms, and separates the films of the plurality of wafers on the first carrying platform from the substrates.

### TECHNICAL FIELD

Embodiments of the present disclosure relate to a field of wafer processing, and more particularly to a wafer processing system.

### BACKGROUND

A solar cell is a device for directly converting optical energy to electric energy through a photoelectric effect or a photochemical effect. A current film-type solar cell working under the photoelectric effect is taken as a mainstream solar cell, and a main function element is a photovoltaic film.

During the process of a traditional film solar cell, it is necessary to remove a sacrificial layer from a photovoltaic film fitted to a wafer substrate through processes such as etching, and then the photovoltaic film is separated from the substrate by using a separation instrument for the convenience of further processing. The separated substrate can be repeatedly used for preparing the photovoltaic film.

The above process may be completed in an epitaxial lift-off system of a solar cell production line. In the epitaxial lift-off system, a wafer with a film is loaded into a carrier, and then the wafer is placed in an etching process chamber to perform a wet etching process. After the etching process is completed, the etched film and the wafer substrate are unloaded, and then the film and the wafer substrate are separated from each other for further respective processing.

In the related art, the bottleneck of the production efficiency of the epitaxial lift-off system is how to complete the unloading and separation of a film and a substrate after the etching process, quickly and reliably. In general, the epitaxial lift-off system uses a single manipulator to perform unloading and operation on the film after the film and the substrate are separated. Usually, there is only one unloading position of the epitaxial lift-off system. When there are a plurality of etching process chambers, after the unloading and separation of wafers in one carrier are completed, wafers in another carrier can be continuously unloaded and separated only by waiting for loading the another carrier to the unloading position. Therefore, a wafer processing system with high film unloading, and separation efficiency is expected.

### BRIEF SUMMARY

### (1) Technical Problem to be Solved

An objective of embodiments of the present disclosure is to provide a wafer processing system with high film unloading separation efficiency, thereby improving the production efficiency.

### (2) Technical Solution

In order to solve the above technical problem, the present disclosure provides a wafer processing system. A wafer includes a substrate and a film on the substrate. The wafer processing system includes: an etching unit, configured to output a plurality of wafers to be separated; and a separation unit, including at least two first carrying platforms and a manipulator component, wherein the at least two first carrying platforms are provided on a side of the etching unit, and are configured to carry the plurality of wafers to be separated, and the manipulator component is switched in turns at each position of all the first carrying platforms, and separates the films of the plurality of wafers on the first carrying platform from the substrates.

In an exemplary embodiment, the wafer processing system further includes: an assembly unit, provided on a side of the separation unit, and configured to assemble a separated film with a frame.

In an exemplary embodiment, the etching unit, the separation unit and the assembly unit are arranged along a first transverse direction. The manipulator component includes: a first manipulator, configured to pick up the plurality of wafers on the first carrying platforms and strip the films of the plurality of wafers from the substrates; and a first linear module, extending along the first transverse direction, wherein the first manipulator is provided on the first linear module, and the first linear module drives the first manipulator to move between the at least two first carrying platforms and the assembly unit.

In an exemplary embodiment, the at least two first carrying platforms of the separation unit are arranged along a second transverse direction perpendicular to the first transverse direction. The manipulator component further includes: a second linear module, extending along the second transverse direction, wherein the first linear module is provided on the second linear module, and the second linear module drives the first linear module and the first manipulator to be switched in turns at each position of all the first carrying platforms.

In an exemplary embodiment, the first manipulator includes a plurality of separation sub-units provided side by side, each separation sub-unit being configured to pick up one of the wafers on the corresponding first carrying platform and strip the film of the wafer from the substrate.

In an exemplary embodiment, the assembly unit includes: a second carrying platform, provided on a side of the separation unit, and configured to carry the separated film; at least one first image sensor, provided above the second carrying platform, and configured to position the separated film; a third carrying platform, provided on a side of the second carrying platform, and configured to carry the frame; at least one second image sensor, provided above the third carrying platform, and configured to position the frame; and a second manipulator, provided between the second carrying platform and the third carrying platform, and configured to move the film on the second carrying platform to the third carrying platform and assemble the film with the frame.

In an exemplary embodiment, the second carrying platform is a rotary carrying platform, the second carrying platform rotates to switch the film at a plurality of positions, and the plurality of positions include an image acquisition position of the at least one first image sensor, and/or a pickup position of the second manipulator.

In an exemplary embodiment, the second manipulator is in signal connection with the at least one first image sensor, and is configured to modify a placement position of the film on the third carrying platform according to an image signal of the at least one first image sensor.

In an exemplary embodiment, the assembly unit further includes: a third linear module, connected to the third carrying platform, and configured to output the assembled film from the system.

In an exemplary embodiment, the film is a photovoltaic flexible film.

### (3) Beneficial Effect

According to the wafer processing system provided in some embodiments of the present disclosure, the separation unit includes at least two first carrying platforms and a manipulator component, a plurality of wafers to be separated can be carried in each first carrying platform, the manipulator component is switched in turns at each position of all the first carrying platforms, and the films of the plurality of wafers on the corresponding first carrying platforms are stripped from the substrate, so that the film and the substrate are separated from each other at a physical position. By means of the above improved structure, when the manipulator component separates the wafer on one of the first carrying platforms, another first carrying platforms can simultaneously load wafers to be separated. Compared with a traditional production line, cyclic switching of the manipulator component between various first carrying platforms shortens time when the manipulator component waits for the first carrying platforms to load wafers, and improves the film unloading efficiency, thereby improving the production yield and the production efficiency to a great extent.

In a exemplary embodiment, the first manipulator includes a plurality of separation sub-units provided side by side, and each of the plurality of separation sub-units is configured to unload one of the wafers, so that a single manipulator component can simultaneously unload a plurality of wafers to be separated on the corresponding first carrying platform, thereby improving the unloading and production efficiency.

In a exemplary embodiment, the wafer processing system further includes an assembly unit configured to assemble the unloaded film with a frame. In the assembly unit, the second carrying platform can be a rotary carrying platform. The second carrying platform rotates to switch the film at a plurality of positions, wherein the plurality of positions include an image acquisition position of the at least one first image sensor, and/or a pickup position of the second manipulator, so as to achieve quick switching of batch films between the plurality of positions, thereby improving the production efficiency. The second manipulator is in signal connection with the at least one first image sensor, and can modify a placement position of the film on the third carrying platform according to the image signal of the at least one first image sensor, thereby improving the accuracy of assembling of the film and the frame.

### BRIEF DESCRIPTION OF THE DRAWINGS

FIG. 1 is a schematic structure diagram of a wafer processing system according to an embodiment of the present disclosure.

### DETAILED DESCRIPTION

The specific implementation manners of the present disclosure will be further described in detail below with reference to the accompanying drawings and embodiments. The following examples are used to illustrate the present disclosure, but are not used to limit the scope of the present disclosure.

In the description of the present disclosure, unless otherwise specified and limited, it should be noted that terms “mounting”, “mutual connection” and “connection” should be generally understood. For example, the term may be fixed connection, or detachable connection or integrated connection, may be mechanical connection or electrical connection, may be direct connection, may be indirect connection through an intermediate, or may be internal communication between two elements. A person of ordinary skill in the art may understand specific meanings of the above terms in the present disclosure according to specific situations.

An embodiment of the present disclosure provides a wafer processing system, wherein a wafer to be processed includes a substrate and a film on the substrate. The wafer processing system of the embodiment can be, for example, used as an epitaxial lift-off system on a solar thin-film cell production line, wherein the wafer to be processed can include, for example, a gallium arsenide substrate and a photovoltaic flexible film fitted to the gallium arsenide substrate. The photovoltaic film can be combined with a polymer frame after being separated from the gallium arsenide substrate, thereby forming a solar film cell.

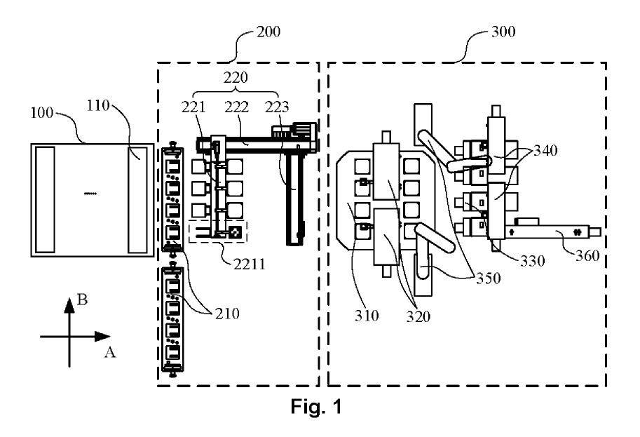

FIG. 1 shows a schematic structure diagram of a wafer processing system according to an embodiment of the present disclosure. The wafer processing system includes an etching unit 100 and a separation unit 200. The etching unit 100 outputs a plurality of wafers to be separated. The etching unit 100 includes a chamber 110. In an etching process, the plurality of wafers are usually placed in a carrier, and then the wafers and the carrier are placed in the chamber 110 of the etching unit 100. After the wafers are etched in the chamber 110 of the etching unit 100, the carrier and the wafers can be transmitted from an outlet of the process chamber to a first carrying platform 210 by using a device such as a manipulator.

In the etching process, a sacrificial layer between a substrate of the wafer and a film is removed, the substrate and the film are only partially adhered, and the separation unit 200 of the present disclosure is used for further separating the film of an etched wafer from a physical position of the substrate.

The separation unit 200 includes at least two first carrying platforms 210 and a manipulator component 220, wherein the at least two first carrying platforms 210 are provided on a side of the etching unit 100, and the first carrying platforms 210 are configured to carry a plurality of wafers to be separated, and the manipulator component 220 is switched in turns at each position of all the first carrying platforms 210, and separates the films of the plurality of wafers on the corresponding first carrying platform 210 from the substrates. The manipulator component 220 can be switched to be in positional correspondence to one first carrying platform 210 each time, and correspondingly separates all wafers on one first carrying platform 210 each time. Meanwhile, another first carrying platforms 210 can load the wafers to be separated. The manipulator component 220 can also be switched to be in positional correspondence to a plurality of first carrying platforms 210 each time, and correspondingly separates all wafers on the plurality of first carrying platforms 210 each time. Meanwhile, another first carrying platforms 210 may still load the wafers to be separated. In the present embodiment, the manipulator component 220 can be, for example, cyclically switched at each position of two first carrying platforms 210, and the manipulator component 220 is switched to be in positional correspondence to one first carrying platform 210 each time.

The wafer processing system may further include an assembly unit 300, provided on a side of the separation unit 200, and configured to assemble the separated film with a frame.

In the present embodiment, the etching unit 100, the separation unit 200 and the assembly unit 300 are arranged along a first transverse direction. The manipulator component 220 includes a first manipulator 221 and a first linear module 222. The first manipulator 221 is configured to pick up the plurality of wafers on the corresponding first carrying platforms 210 and strip the films of the plurality of wafers from the substrates. The first linear module 222 extends along the first transverse direction A, the first manipulator 221 is provided on the first linear module 222, and the first linear module 222 drives the first manipulator 221 to move between the at least two first carrying platforms 210 and the assembly unit 300.

The at least two first carrying platforms 210 of the separation unit 200 can be arranged along a second transverse direction B perpendicular to the first transverse direction A. The manipulator component 220 can further include a second linear module 223. The second linear module 223 extends along the second transverse direction B, the first linear module 222 is provided on the second linear module 223, and the second linear module 223 drives the first linear module 222 and the first manipulator 221 to be switched in turns at the position of the at least two first carrying platforms 210.

The first manipulator 221 can include a plurality of separation sub-units 2211 provided side by side, each separation sub-unit 2211 being configured to pick up one of the wafers on the corresponding first carrying platform 210 and strip the film of the wafer from the substrate.

The assembly unit 300 can includes a second carrying platform 310, at least one first image sensor 320, a third carrying platform 330, at least one second image sensor 340, and a second manipulator 350. The second carrying platform 310 is provided on a side of the separation unit 200, and is configured to carry the separated film. The at least one first image sensor 320 is provided above the second carrying platform 310, and is configured to position the separated film. The third carrying platform 330 is provided on a side of the second carrying platform 310, and is configured to carry the frame. The at least one second image sensor 340 is provided above the third carrying platform 330, and is configured to position the frame. The second manipulator 350 is provided between the second carrying platform 310 and the third carrying platform 330, and is configured to move the film on the second carrying platform 310 to the third carrying platform 330 and assemble the film with the frame. In addition, the assembly unit 300 can further include a third linear module 360, connected to the third carrying platform 330 and configured to output the assembled film from the system.

In the present embodiment, the second carrying platform 310 is a rotary carrying platform, the second carrying platform 310 rotates to switch the film at a plurality of positions, and the plurality of positions include an image acquisition position of the at least one first image sensor 320, and/or a pickup position of the second manipulator 350.

The second manipulator 350 can be in signal connection with the at least one first image sensor 320, and is configured to modify a placement position of the film on the third carrying platform 330 according to an image signal of the at least one first image sensor 320.

For a large-productivity production system, the etching unit 100 usually includes a plurality of chambers 110 for an etching process, which are lined for example. The plurality of chambers 110 of the etching unit 100 output a plurality of wafers to be separated. The wafers to be separated can be loaded on at least two first carrying platforms 210. The first manipulator 221 can be movably switched between the at least two first carrying platforms 210 under the drive of the second linear module 223, and takes out and separates the plurality of wafers on the corresponding first carrying platforms 210 to obtain a separated film and a substrate, wherein the separated substrate can be conveyed to a substrate cleaning recovery device, so as to achieve reuse of the substrate, which will not be elaborated herein. The first linear module 222 drives the first manipulator 221 to convey the separated film to the second carrying platform 310, a plurality of first image sensors 320 may be provided above the second carrying platform 310, the plurality of films can be placed at image acquisition positions of the plurality of first image sensors 320, after the plurality of first image sensors 320 perform shooting positioning on the plurality of films, the second carrying platform 310 starts to rotate, for example, along the center at 180°, the plurality of films are switched to the pickup position of the second manipulator 350, the second manipulator 350 picks up the plurality of films and conveys the films to the third carrying platform 330, and the films are assembled with a plurality of frames placed on the third carrying platform 330, so that the films and the frames are integrated. There can also be a plurality of second image sensors 340 on the third carrying platform 330, the frames on the third carrying platform 330 can be visually positioned to ensure a more accurate relative position of the films on the frames. The films and the frames can be conveyed out of the system through the third linear module 360 after being assembled, for example, conveyed into a storage basket.

According to the wafer processing system provided in the present disclosure, the separation unit 220 includes at least two first carrying platforms 210 and a manipulator component 220, a plurality of wafers to be separated may be carried in the first carrying platforms 210, the manipulator component 220 is switched in turns at each position of all the first carrying platforms 210, and the films of the plurality of wafers on the corresponding first carrying platforms 210 are separated from the substrate. By means of the above improved structure, when the manipulator component 220 separates the wafer on one or some of the first carrying platforms 210, another first carrying platforms 210 can simultaneously load wafers to be separated. Compared with a traditional production line, cyclic switching of the manipulator component 220 between various first carrying platforms 210 shortens time when the manipulator component 220 waits for the first carrying platforms 210 to load wafers, and improves the film unloading efficiency, thereby improving the production yield and the production efficiency to a great extent.

Since the first manipulator 221 includes a plurality of separation sub-units 2211 provided side by side, and each of the plurality of separation sub-units 2211 is configured to unload and separate one of the wafers, so that a single manipulator component 220 may simultaneously unload and separate a plurality of wafers to be separated on a first carrying platform 210, thereby improving the separating and production efficiency.

The wafer processing system of the present embodiment further includes an assembly unit 300 configured to assemble the separated film with a frame. In the assembly unit 300, the second carrying platform 310 can be a rotary carrying platform. The second carrying platform 310 rotates to switch the film at a plurality of positions, wherein the plurality of positions include an image acquisition position of the at least one first image sensor 320, and/or a pickup position of the second manipulator 350, so as to achieve quick switching of batch films between the plurality of positions, thereby improving the production efficiency. The second manipulator 350 is in signal connection with the at least one first image sensor 320, and can modify a placement position of the film on the third carrying platform 330 according to an image signal of the at least one first image sensor 320, thereby improving the accuracy of assembling of the film and the frame.

The wafer processing system of the present disclosure achieves automated separation and quick unloading of a film from a substrate, is convenient and quick, improves the yield and the production efficiency to a great extent, and reduces the production cost. Moreover, the above system has a simple structure, and is easy to operate and maintain, relatively low in cost, and easy to achieve and implement.

The above is only the exemplary embodiments of the present disclosure, and is not intended to limit the present disclosure. Any modifications, equivalent replacements, improvements and the like made within the spirit and principle of the present disclosure shall fall within the protection scope of the present disclosure.

What is claimed is:

1. A wafer processing system, a wafer comprising a substrate and a film on the substrate, the wafer processing system comprising:
an etching unit, configured to output a plurality of wafers to be separated; and
a separation unit, comprising at least two first carrying platforms and a manipulator component, wherein the at least two first carrying platforms are provided on a side of the etching unit, and are configured to carry the plurality of wafers to be separated, and the manipulator component is switched in turns at each position of all the first carrying platforms, and separates the films of the plurality of wafers on the first carrying platform from the substrates.

2. The wafer processing system as claimed in claim 1, further comprising:
an assembly unit, provided on a side of the separation unit, and configured to assemble a separated film with a frame.

3. The wafer processing system as claimed in claim 2, wherein the etching unit, the separation unit and the assembly unit are arranged along a first transverse direction, and the manipulator component comprises:
a first manipulator, configured to pick up the plurality of wafers on the first carrying platforms and strip the films of the plurality of wafers from the substrates; and
a first linear module, extending along the first transverse direction, the first manipulator being provided on the first linear module, and the first linear module driving the first manipulator to move between the at least two first carrying platforms and the assembly unit.

4. The wafer processing system as claimed in claim 3, wherein the at least two first carrying platforms of the separation unit are arranged along a second transverse direction perpendicular to the first transverse direction, and the manipulator component further comprises:
a second linear module, extending along the second transverse direction, the first linear module being provided on the second linear module, and the second linear module driving the first linear module and the first manipulator to be switched in turns at each position of all the first carrying platforms.

5. The wafer processing system as claimed in claim 3, wherein the first manipulator comprises a plurality of separation sub-units provided side by side, each separation sub-unit being configured to pick up one of the wafers on the corresponding first carrying platform and strip the film of the wafer from the substrate.

6. The wafer processing system as claimed in claim 2, wherein the assembly unit comprises:
a second carrying platform, provided on a side of the separation unit, and configured to carry the separated film;
at least one first image sensor, provided above the second carrying platform, and configured to position the separated film;
a third carrying platform, provided on a side of the second carrying, platform, and configured to carry the frame;
at least one second image sensor, provided above the third carrying platform, and configured to position the frame; and
a second manipulator, provided between the second carrying platform and the third carrying platform, and configured to move the film on the second carrying platform to the third carrying platform and assemble the film with the frame.

7. The wafer processing system as claimed in claim 6, wherein the second carrying platform is a rotary carrying platform, and the second carrying platform rotates to switch the film at a plurality of positions, the plurality of positions comprising an image acquisition position of the at least one first image sensor, and/or a pickup position of the second manipulator.

8. The wafer processing system as claimed in claim 6, wherein the second manipulator is in signal connection with the at least one first image sensor, and is configured to modify a placement position of the film on the third carrying platform according to an image signal of the at least one first image sensor.

9. The wafer processing system as claimed in claim 6, wherein the assembly unit further comprises:
a third linear module, connected to the third carrying platform, and configured to output the assembled film from the system.

10. The wafer processing system as claimed in claim 1, wherein the film is a photovoltaic flexible film.
